(19) United States
(12) Patent Application Publication
(10) Pub. No.: US 2024/0168083 A1
(43) Pub. Date: May 23, 2024

(54) SWITCHING DEVICE

(71) Applicant: OMRON Corporation, Kyoto-shi (JP)

(72) Inventors: Tetsuro TSURUSU, Kyoto-shi (JP); Toshinobu AKUTAGAWA, Kyoto-shi (JP)

(21) Appl. No.: 18/487,123

(22) Filed: Oct. 16, 2023

(30) Foreign Application Priority Data
Nov. 21, 2022 (JP) 2022-185461

(51) Int. Cl. G01R 31/28; H03H 7/01

(52) U.S. Cl. CPC G01R 31/2834; H03H 7/0115

(57) ABSTRACT

A switching device includes a base, a first DUT terminal, a first DC terminal, a first RF terminal, a first low-pass filter, and a first switching section. The first DUT terminal is a terminal for a device under test and is arranged on the base. The first DC terminal is a terminal for a DC test and is arranged on the base. The first RF terminal is a terminal for an RF test and is arranged on the base. The first low-pass filter is connected to the first DUT terminal and the first DC terminal. The first switching section is switchable between an on state and an off state. The first switching section electrically connects the first DUT terminal and the first RF terminal in the on state. The first switching section electrically disconnects the first DUT terminal and the first RF terminal in the off state.

### CROSS-REFERENCE TO RELATED APPLICATION

This application claims priority to Japanese Patent Application No. 2022-185461, filed Nov. 21, 2022. The contents of that application are incorporated by reference herein in their entirety.

### FIELD

The claimed invention relates to a switching device.

### BACKGROUND

In a test device such as a semiconductor test apparatus as disclosed, for example, in Japanese Patent Application Laid-Open No. 2007-184155, a switching device is used to switch between testing of the high-frequency characteristics of a device under test (hereinafter referred to as an RF test) and testing of DC characteristics such as input voltage and output voltage of the direct current (hereinafter referred to as a DC test). The switching device includes, for example, a C-contact type relay. During the RF test, the switching device connects the circuit for the RF test of the test equipment and the device under test. During the DC test, the switching device connects the circuit for the DC test of the test equipment and the device under test.

### SUMMARY

In the above switching device, when the frequency of switching between the circuit for the RF test and the circuit for the DC test increases due to long-term use, the switching device wears out and the accuracy of the test may deteriorate. For example, if the switching device includes a C-contact type relay, the contact resistance of the contacts in the relay may increase as the number of opening and closing times of the contacts increases. In that case, the accuracy of the DC test will decrease. It is an object of the claimed invention to maintain stable and highly accurate measurement in a switching device even after long-term use.

A switching device according to an aspect of the claimed invention is a switching device for switching between an RF test and a DC test. The switching device includes a base, a first DUT terminal, a first DC terminal, a first RF terminal, a first low-pass filter, and a first switching section. The first DUT terminal is a terminal for a device under test, and is arranged on the base. The first DC terminal is a terminal for the DC test, and is arranged on the base. The first RF terminal is a terminal for the RF test and is arranged on the base. The first low-pass filter is connected to the first DUT terminal and the first DC terminal. The first switching section is connected to the first DUT terminal and the first RF terminal. The first switching section is switchable between an on state and an off state. The first switching section electrically connects the first DUT terminal and the first RF terminal in the on state. The first switching section electrically disconnects the first DUT terminal and the first RF terminal in the off state.

In the switching device according to the present aspect, the first switching section electrically connects the first DUT terminal and the first RF terminal in the on state. In this state, a signal for the RF test (hereinafter referred to as an RF signal) passes through the first DUT terminal and the first RF terminal and is detected by a test equipment. On the other hand, since the RF signal is cut by the low-pass filter, the RF signal is prevented from flowing to the first DC terminal.

Further, the first switching section electrically disconnects the first DUT terminal and the first RF terminal in the off state. In this state, a signal for the DC test (hereinafter referred to as a DC signal) is prevented from flowing to the first RF terminal. The DC signal passes through the first DUT terminal, the low-pass filter, and the first DC terminal and is detected by the test equipment. Therefore, the DC signal is detected by the test equipment without passing through the first switching section. Thereby, even if the first switching section wears out, it is possible to measure the DC signal stably and accurately. As described above, the switching device according to the present aspect maintains stable and highly accurate measurement even in long-term use.

A switching device according to another aspect of the claimed invention is a switching device for switching between a DC test for a device under test and a loopback test for testing high-frequency characteristics. The switching device includes a base, a first DC terminal, a first loopback terminal, a second DC terminal, a second loopback terminal, a third DC terminal, a third loopback terminal, a fourth DC terminal, a fourth loopback terminal, a first low-pass filter, a second low-pass filter, a third low-pass filter, a fourth low-pass filter, a first switching section, and a second switching section. The first to fourth DC terminals are terminals for the DC test, and are arranged on the base. The first to fourth loopback terminals are terminals for the loopback test, and are arranged on the base.

The first low-pass filter is connected to the first loopback terminal and the first DC terminal. The second low-pass filter is connected to the second loopback terminal and the second DC terminal. The third low-pass filter is connected to the third loopback terminal and the third DC terminal. The fourth low-pass filter is connected to the fourth loopback terminal and the fourth DC terminal. The first switching section is connected to the first loopback terminal and the third loopback terminal.

The first switching section is switchable between an on state and an off state. The first switching section electrically connects the first loopback terminal and the third loopback terminal in the on state. The first switching section electrically disconnects the first loopback terminal and the third loopback terminal in the off state. The second switching section is connected to the second loopback terminal and the fourth loopback terminal. The second switching section is switchable between an on state and an off state. The second switching section electrically connects the second loopback terminal and the fourth loopback terminal in the on state. The second switching section electrically disconnects the second loopback terminal and the fourth loopback terminal in the off state.

In the switching device according to the present aspect, the first switching section electrically connects the first loopback terminal and the third loopback terminal in the on state. In addition, the second switching section electrically connects the second loopback terminal and the fourth loopback terminal in the on state. In this state, the RF signal for the loopback test returns to the device under test through the first loopback terminal and the third loopback terminal. Also, the RF signal for the loopback test returns to the device under test through the second loopback terminal and the fourth loopback terminal. On the other hand, since the RF signal is cut by the first to fourth low-pass filters, the RF signal is prevented from flowing through the first to fourth DC terminals.

The first switching section electrically disconnects the first loopback terminal and the third loopback terminal in the off state. The second switching section electrically disconnects the second loopback terminal and the fourth loopback terminal in the off state. In this state, the DC signal passes through the first loopback terminal, the first low-pass filter, and the first DC terminal and is detected by the test equipment. The DC signal passes through the second loopback terminal, the second low-pass filter, and the second DC terminal and is detected by the test equipment. The DC signal passes through the third loopback terminal, the third low-pass filter, and the third DC terminal and is detected by the test equipment. The DC signal passes through the fourth loopback terminal, the fourth low-pass filter, and the fourth DC terminal and is detected by the test equipment. Therefore, the DC signal is detected by the test equipment without passing through the first switching section and the second switching section. Thereby, even if the first switching section and the second switching section are worn out, it is possible to measure the DC signal stably and accurately. As described above, the switching device according to the present aspect maintains stable and highly accurate measurement even in long-term use.

### BRIEF DESCRIPTION OF THE DRAWINGS

FIG. 1 is a diagram showing a configuration of a switching device according to a first exemplary embodiment of the claimed invention.

FIG. 2 is a diagram showing a configuration of a switching device according to a second exemplary embodiment of the claimed invention.

FIG. 3 is a diagram showing an arrangement of terminals according to a first modification of the second embodiment of the claimed invention.

FIG. 4 is a diagram showing an arrangement of the terminals according to a second modification of the second embodiment of the claimed invention.

FIG. 5 is a diagram showing an arrangement of the terminals according to a third modification of the second embodiment.

FIG. 6 is a diagram showing an arrangement of the terminals according to a fourth modification of the second embodiment of the claimed invention.

FIG. 7 is a diagram showing an arrangement of terminals according to a fifth modification of the second embodiment of the claimed invention.

FIG. 8 is a diagram showing an arrangement of the terminals according to a sixth modification of the second embodiment of the claimed invention.

FIG. 9 is a diagram showing a configuration of a switching device according to a third embodiment of the claimed invention.

FIG. 10 is a diagram showing an arrangement of the terminals according to a modification of the third embodiment of the claimed invention.

FIG. 11 is a diagram showing a configuration of a switching device according to a fourth embodiment of the claimed invention.

FIG. 12 is a diagram showing the switching device and signal flow during a loopback test.

FIG. 13 is a diagram showing the switching device and signal flow during a DC test.

FIG. 14 is a diagram showing a configuration of a switching device according to a modification of the first embodiment of the claimed invention.

### DETAILED DESCRIPTION

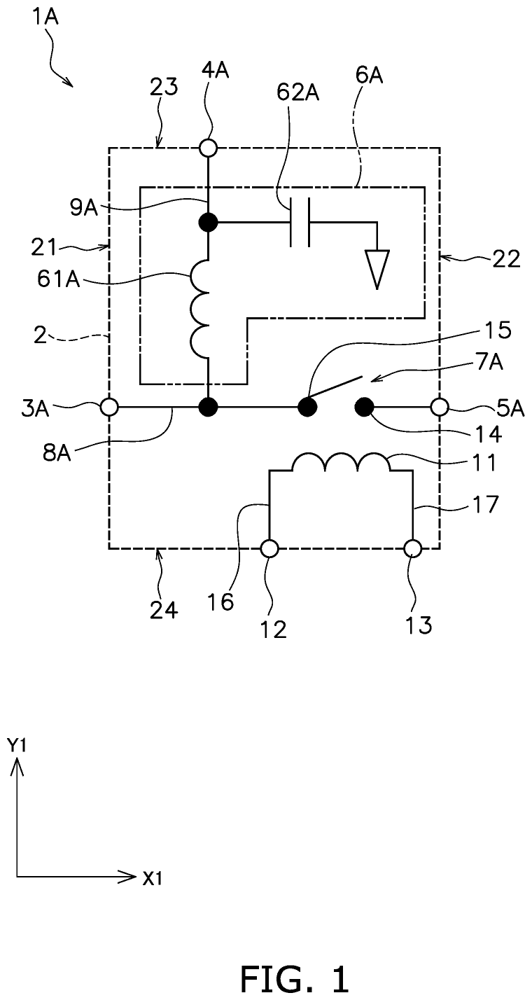

Hereinafter, a switching device according to an embodiment will be described with reference to the drawings. FIG. 1 is a diagram showing the configuration of a switching device 1A according to a first embodiment of the claimed invention. The switching device 1A is a device for switching between an RF test and a DC test for a device under test (hereinafter referred to as a DUT). The DUT is, for example, an electronic component such as a semiconductor. The switching device 1A connects the DUT and ATE (Automated Test Equipment) such as semiconductor inspection equipment.

As shown in FIG. 1, the switching device 1A includes a base 2, a first DUT terminal 3A, a first DC terminal 4A, a first RF terminal 5A, a first low-pass filter 6A, a first switching section 7A, a drive section 11, a first drive terminal 12, and a second drive terminal 13. The base 2 includes, for example, a substrate, a lead frame, or a resin molded product provided with a transmission path. The first DUT terminal 3A, the first DC terminal 4A, the first RF terminal 5A, the first low-pass filter 6A, the first switching section 7A, the drive section 11, the first drive terminal 12, and the second drive terminal 13 are arranged on the base 2. The switching device 1A is modularized by arranging the first DUT terminal 3A, the first DC terminal 4A, the first RF terminal 5A, the first low-pass filter 6A, the first switching section 7A, the drive section 11, the first drive terminal 12, and the second drive terminal 13 on the common base 2.

The first DUT terminal 3A is a terminal for the DUT. The first DUT terminal 3A is connected to the DUT. The first DC terminal 4A is a terminal for the DC test. The first DC terminal 4A is connected to a terminal for the DC test of the ATE. The first RF terminal 5A is a terminal for the RF test. The first RF terminal 5A is connected to a terminal for the RF test of the ATE.

The first low-pass filter 6A is connected to the first DUT terminal 3A and the first DC terminal 4A. The first low-pass filter 6A includes an inductor 61A and a capacitor 62A. The first low-pass filter 6A has a lower limit of the cut frequency set so as to pass the DC signal but cut the RF signal. For example, the first low-pass filter 6A cuts high frequency signals of 100 kHz or higher.

The first switching section 7A is connected to the first DUT terminal 3A and the first RF terminal 5A. The first switching section 7A is switchable between an on state and an off state. The first switching section 7A electrically connects the first DUT terminal 3A and the first RF terminal 5A in the on state. The first switching section 7A electrically disconnects the first DUT terminal 3A and the first RF terminal 5A in the off state.

The drive section 11 switches the first switching section 7A between the on state and the off state. The drive section 11 is connected to the first drive terminal 12 and the second drive terminal 13. By causing current to flow through the drive section 11 via the first drive terminal 12 and the second drive terminal 13, the drive section 11 switches the first switching section 7A from the off state to the on state. By cutting off the current to the drive section 11, the drive section 11 switches the first switching section 7A from the on state to the off state. Conversely, by causing current to flow through the drive section 11 via the first drive terminal 12 and the second drive terminal 13, the drive section 11 may switch the first switching section 7A from the on state to the off state.

The first switching section 7A and the drive section 11 may, for example, be a mechanical relay. The first switching section 7A includes a fixed contact 14 and a movable contact 15. The drive section 11 includes a coil. When the movable contact 15 is in contact with the fixed contact 14, the first switching section 7A is in the on state. When the movable contact 15 is separated from the fixed contact 14, the first switching section 7A is in the off state.

In the switching device 1A according to the first embodiment of the claimed invention, the first switching section 7A is set to the on state during the RF test. Thereby, the first DUT terminal 3A and the first RF terminal 5A are electrically connected to each other. In this state, the RF signal is detected by the ATE through the first DUT terminal 3A and the first RF terminal 5A. On the other hand, since the RF signal is cut by the first low-pass filter 6A, the RF signal is prevented from flowing to the first DC terminal 4A.

During the DC test, the first switching section 7A is set to the off state. Thereby, the first DUT terminal 3A and the first RF terminal 5A are electrically isolated from each other. In this state, the DC signal is prevented from flowing to the first RF terminal 5A. The DC signal passes through the first DUT terminal 3A, the first low-pass filter 6A, and the first DC terminal 4A and is detected by the ATE. Therefore, the DC signal is detected by the ATE without passing through the first switching section 7A. Thereby, even if the first switching section 7A is worn out, stable and highly accurate measurement is still possible. For example, stable and highly accurate measurement is possible regardless of wear or changes in the contact resistance of the contacts 14 and 15.

The base 2 includes a first side edge 21, a second side edge 22, a third side edge 23, and a fourth side edge 24. The second side edge 22 is arranged to face the first side edge 21 in a first direction X1. The second side edge 22 is located opposite the first side edge 21. The third side edge 23 extends in the first direction X1 and is connected to the first side edge 21 and the second side edge 22. The fourth side edge 24 extends in the first direction X1 and is connected to the first side edge 21 and the second side edge 22. The fourth side edge 24 is arranged to face the third side edge 23 in a second direction Y1. The fourth side edge 24 is located opposite the third side edge 23.

The first DUT terminal 3A, the first DC terminal 4A, the first RF terminal 5A, the first drive terminal 12, and the second drive terminal 13 are arranged on the side edges of the base 2. Specifically, the first DUT terminal 3A is arranged on the first side edge 21. The first RF terminal 5A is arranged on the second side edge 22. The first DUT terminal 3A and the first RF terminal 5A are arranged side-by-side with each other in the first direction X1. The first DUT terminal 3A and the first RF terminal 5A are arranged facing each other in the first direction X1. The first DC terminal 4A is arranged on the third side edge 23. The first drive terminal 12 and the second drive terminal 13 are arranged on the fourth side edge 24.

The base 2 includes a first RF line 8A and a first DC line 9A. The first RF line 8A and the first DC line 9A are transmission paths through which signals flow. The RF signal flows through the first RF line 8A. The DC signal flows through the first DC line 9A. The first RF line 8A extends from the first DUT terminal 3A to the first RF terminal 5A. The first RF line 8A extends linearly in the first direction X1. The first switching section 7A is connected to the first RF line 8A. The first DC line 9A extends from the first DUT terminal 3A to the first DC terminal 4A. The first low-pass filter 6A is connected to the first DC line 9A.

The base 2 includes a first drive line 16 and a second drive line 17. The first drive line 16 extends from the drive section 11 to the first drive terminal 12. The second drive line 17 extends from the drive section 11 to the second drive terminal 13. It should be noted that the arrangement of each terminal and each line is not limited to the above arrangement, and may be changed.

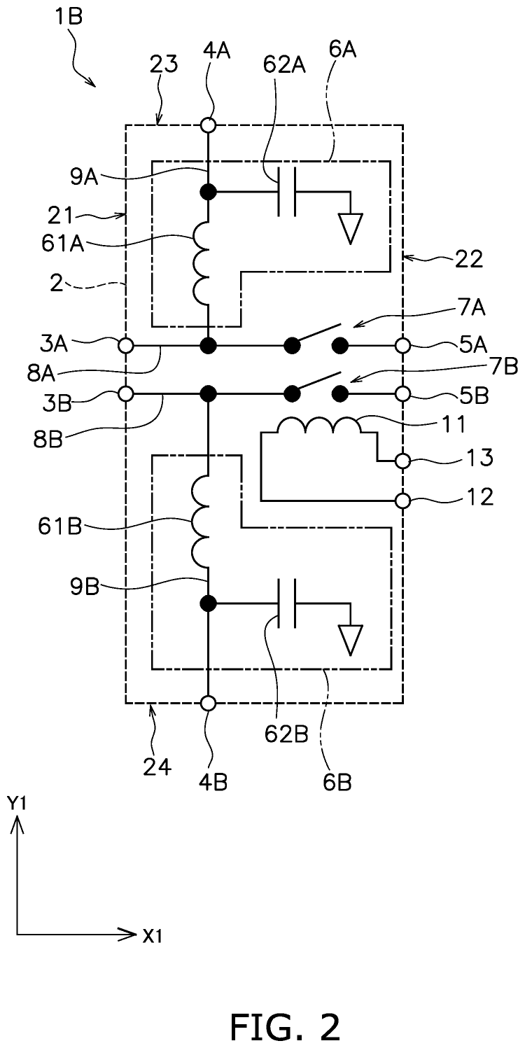

Next, a switching device 1B according to a second embodiment of the claimed invention will be described. FIG. 2 is a diagram showing a configuration of the switching device 1B according to the second embodiment. As shown in FIG. 2, in addition to the configuration of the switching device 1A according to the first embodiment, the switching device 1B includes a second DUT terminal 3B, a second DC terminal 4B, a second RF terminal 5B, a second low-pass filter 6B, and a second switching section 7B.

The first and second DUT terminals 3A and 3B, the first and second DC terminals 4A and 4B, the first and second RF terminals 5A and 5B, the first and second low-pass filters 6A and 6B, the first and second switching sections 7A and 7B, the drive section 11, and the first and second drive terminals 12 and 13 are arranged on the base 2. The switching device 1B is modularized by arranging the first and second DUT terminals 3A and 3B, the first and second DC terminals 4A and 4B, the first and second RF terminals 5A and 5B, the first and second low-pass filters 6A and 6B, the first and second switching sections 7A and 7B, the drive section 11, and the first and second drive terminals 12 and 13 on the common base 2.

The configurations of the second DUT terminal 3B, the second DC terminal 4B, and the second RF terminal 5B are the same as those of the first DUT terminal 3A, the first DC terminal 4A, and the first RF terminal 5A, respectively. The second low-pass filter 6B is connected to the second DUT terminal 3B and the second DC terminal 4B. The second low-pass filter 6B includes an inductor 61B and a capacitor 62B. The second low-pass filter 6B has a lower limit of the cut frequency set so as to pass the DC signal but cut the RF signal. The other configuration of the second low-pass filter 6B is the same as that of the first low-pass filter 6A.

The second switching section 7B is connected to the second DUT terminal 3B and the second RF terminal 5B. The second switching section 7B is switchable between an on state and an off state. The second switching section 7B electrically connects the second DUT terminal 3B and the second RF terminal 5B in the on state. The second switching section 7B electrically disconnects the second DUT terminal 3B and the second RF terminal 5B in the off state. The drive section 11 switches the first and second switching sections 7A and 7B between their on and off states.

In the switching device 1B according to the second embodiment, the first and second switching sections 7A and 7B are set to the on state during the RF test. Thereby, the first DUT terminal 3A and the first RF terminal 5A are electrically connected to each other. The second DUT terminal 3B and the second RF terminal 5B are electrically connected to each other. In this state, the RF signal passes through the first DUT terminal 3A and the first RF terminal 5A and is detected by the ATE. Further, the RF signal passes through the second DUT terminal 3B and the second RF terminal 5B and is detected by the ATE. On the other hand, since the RF signal is cut by the first and second low-pass filters 6A and 6B, the RF signal is prevented from flowing to the first and second DC terminals 4A and 4B.

During the DC test, the first and second switching sections 7A and 7B are set to their off states. Thereby, the first DUT terminal 3A and the first RF terminal 5A are electrically isolated from each other. The second DUT terminal 3B and the second RF terminal 5B are electrically isolated from each other. In this state, the DC signal is prevented from flowing to the first RF terminal 5A and the second RF terminal 5B. The DC signal passes through the first DUT terminal 3A, the first low-pass filter 6A, and the first DC terminal 4A, and is detected by the ATE. Further, the DC signal passes through the second DUT terminal 3B, the second low-pass filter 6B, and the second DC terminal 4B, and is detected by the ATE. Therefore, the DC signal is detected by the ATE without passing through the first and second switching sections 7A and 7B. Thereby, even if the first and second switching sections 7A and 7B are worn out, stable and highly accurate measurement is still possible.

The first and second DUT terminals 3A and 3B, the first and second DC terminals 4A and 4B, the first and second RF terminals 5A and 5B, and the first and second drive terminals 12 and 13 are arranged on the side edges of the base 2. Specifically, the first and second DUT terminals 3A and 3B are arranged along the first side edge 21. The first and second RF terminals 5A and 5B are arranged along the second side edge 22.

The first DUT terminal 3A and the first RF terminal 5A are arranged side by side with each other in the first direction X1. The first DUT terminal 3A and the first RF terminal 5A are arranged facing each other in the first direction X1. The second DUT terminal 3B and the second RF terminal 5B are arranged side by side with each other in the first direction X1. The second DUT terminal 3B and the second RF terminal 5B are arranged facing each other in the first direction X1.

In addition to the configuration of the first embodiment, the base 2 further includes a second RF line 8B and a second DC line 9B. The second RF line 8B extends from the second DUT terminal 3B to the second RF terminal 5B. The second RF line 8B extends linearly in the first direction X1. The second RF line 8B is arranged parallel to the first RF line 8A. The second switching section 7B is connected to the second RF line 8B.

The second DC line 9B extends from the second DUT terminal 3B to the second DC terminal 4B. The second low-pass filter 6B is connected to the second DC line 9B. The first DC terminal 4A is arranged on the third side edge 23. The second DC terminal 4B is arranged on the fourth side edge 24. The first drive terminal 12 and the second drive terminal 13 are arranged on the second side edge 22.

Other configurations of the switching device 1B according to the second embodiment are similar to those of the switching device 1A according to the first embodiment. By arranging the first and second DUT terminals 3A and 3b and the first and second RF terminals 5A and 5B as described above, signal loss during differential transmission is reduced.

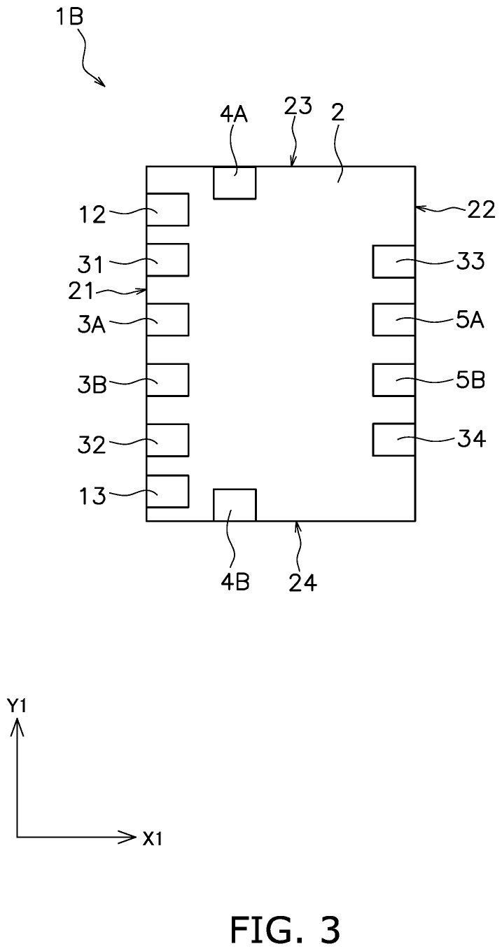

The arrangement of each terminal and each line is not limited to the above and may be changed. For example, FIG. 3 is a diagram showing an arrangement of the terminals according to a first modification of the second embodiment of the claimed invention. As shown in FIG. 3, in the first modification of the second embodiment, the switching device 1B includes a first ground terminal 31, a second ground terminal 32, a third ground terminal 33, and a fourth ground terminal 34.

The first ground terminal 31 is arranged on one side of the first and second DUT terminals 3A and 3B on the first side edge 21. The second ground terminal 32 is arranged on the other side of the first and second DUT terminals 3A and 3B on the first side edge 21. The first and second DUT terminals 3A and 3B are arranged between the first ground terminal 31 and the second ground terminal 32. The first and second DUT terminals 3A and 3B are arranged adjacent to each other in the second direction Y1.

The third ground terminal 33 is arranged on one side of the first and second RF terminals 5A and 5B on the second side edge 22. The fourth ground terminal 34 is arranged on the other side of the first and second RF terminals 5A and 5B on the second side edge 22. The first and second RF terminals 5A and 5B are arranged between the third ground terminal 33 and the fourth ground terminal 34. The first and second RF terminals 5A and 5B are arranged adjacent to each other in the second direction Y1.

By arranging the ground terminals 31 to 34 as described above, noise resistance in the RF test is improved. The arrangement of the first and second drive terminals 12 and 13 and the first and second DC terminals 4A and 4B is not limited to that shown in FIG. 3 and may be changed.

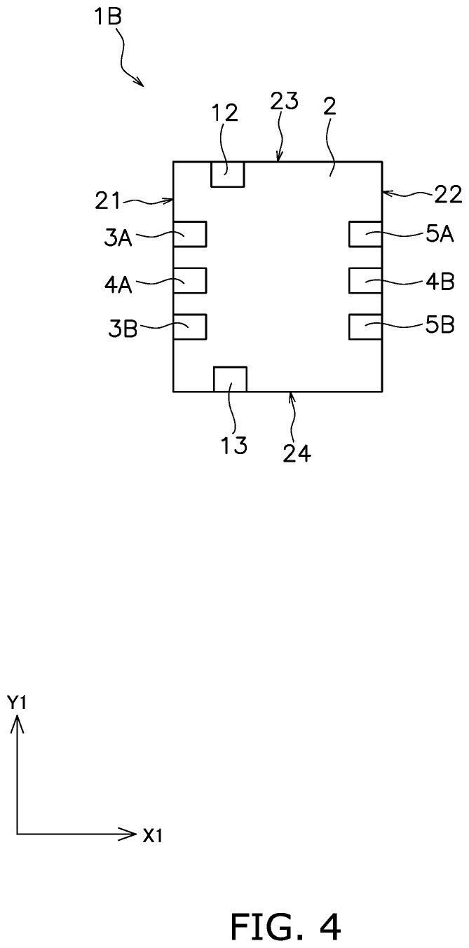

FIG. 4 is a diagram showing an arrangement of the terminals according to the second modification. As shown in FIG. 4, in the second modification, the first DC terminal 4A is arranged between the first DUT terminal 3A and the second DUT terminal 3B on the first side edge 21. The second DC terminal 4B is arranged between the first RF terminal 5A and the second RF terminal 5B on the second side edge 22. The first and second DUT terminals 3A and 3B are arranged symmetrically with respect to the first DC terminal 4A. The first and second RF terminals 5A and 5B are arranged symmetrically with respect to the second DC terminal 4B. Due to the arrangement of the terminals as described above, uniform common-mode noise is applied to the first RF line 8A and the second RF line 8B. This reduces the effects of the common-mode noise on the RF test. It should be noted that the arrangement of the first and second drive terminals 12 and 13 and the first and second DC terminals 4A and 4B is not limited to that shown in FIG. 4 and may be changed.

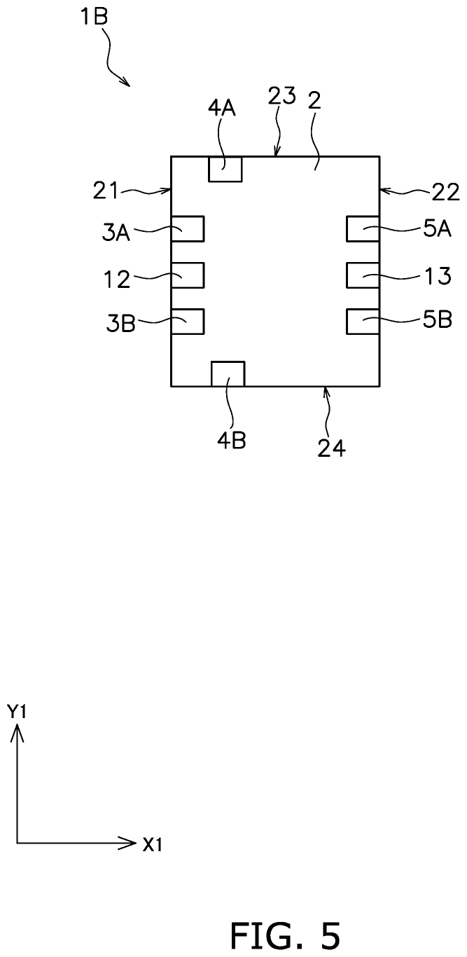

FIG. 5 is a diagram showing an arrangement of the terminals according to a third modification. As shown in FIG. 5, in the third modification, the first drive terminal 12 is arranged between the first DUT terminal 3A and the second DUT terminal 3B on the first side edge 21. The second drive terminal 13 is arranged between the first RF terminal 5A and the second RF terminal 5B on the second side edge 22. The first and second DUT terminals 3A and 3B are arranged symmetrically with respect to the first drive terminal 12. The first and second RF terminals 5A and 5B are arranged symmetrically with respect to the second drive terminal 13. Due to the arrangement of the terminals as described above, uniform common-mode noise is applied to the first RF line 8A and the second RF line 8B. This reduces the effects of the common mode noise on the RF test. It should be noted that the arrangement of the first and second DC terminals 4A and 4B is not limited to that shown in FIG. 5 and may be changed.

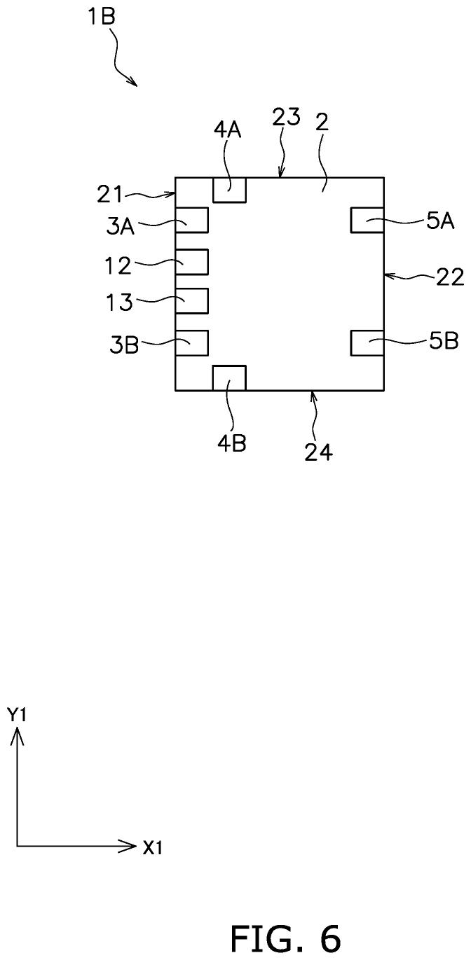

FIG. 6 is a diagram showing an arrangement of the terminals according to a fourth modification. As shown in FIG. 6, in the fourth modification, the first and second drive terminals 12 and 13 are arranged between the first DUT terminal 3A and the second DUT terminal 3B on the first side edge 21. The first and second drive terminals 12 and 13 are arranged adjacent to each other in the second direction Y1. The first and second DUT terminals 3A and 3B are arranged symmetrically with respect to the first and second drive terminals 12 and 13, respectively. Due to the arrangement of the terminals as described above, uniform common-mode noise is applied to the first RF line 8A and the second RF line 8B. This reduces the influence of the common mode noise on the RF test. The arrangement of the first and second DC terminals 4A and 4B is not limited to that shown in FIG. 6, and may be changed.

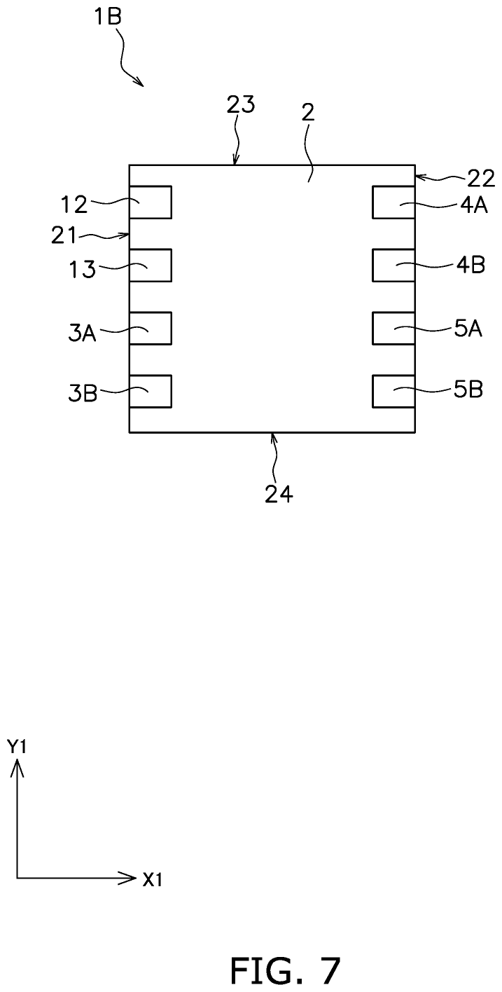

FIG. 7 is a diagram showing an arrangement of the terminals according to a fifth modification. As shown in FIG. 7, in the fifth modification, the first and second DUT terminals 3A and 3B and the first and second drive terminals 12 and 13 are arranged along the first side edge 21. The first and second DUT terminals 3A and 3B are arranged adjacent to each other in the second direction Y1. The first and second drive terminals 12 and 13 are arranged adjacent to each other in the second direction Y1. The second drive terminal 13 and the first DUT terminal 3A are arranged adjacent to each other in the second direction Y1.

The first and second RF terminals 5A and 5B and the first and second DC terminals 4A and 4B are arranged along the second side edge 22. The first and second RF terminals 5A and 5B are arranged adjacent to each other in the second direction Y1. The first and second DC terminals 4A and 4B are arranged adjacent to each other in the second direction Y1. The second DC terminal 4B and the first RF terminal 5A are arranged adjacent to each other in the second direction Y1. Arranging the terminals as described above facilitates the arrangement of the lines on the base 2.

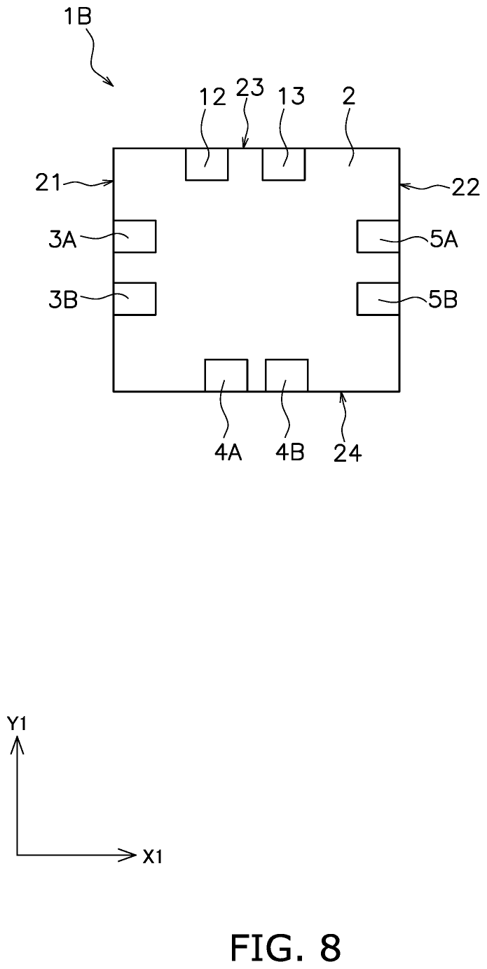

FIG. 8 is a diagram showing an arrangement of the terminals according to a sixth modification. As shown in FIG. 8, in the sixth modification, the first and second DUT terminals 3A and 3B are arranged along the first side edge 21. The first and second RF terminals 5A and 5B are arranged along the second side edge 22. The first and second drive terminals 12 and 13 are arranged along the third side edge 23. The first and second DC terminals 4A and 4B are arranged along the fourth side edge 24. Arranging the terminals as described above facilitates the arrangement of the lines on the base 2.

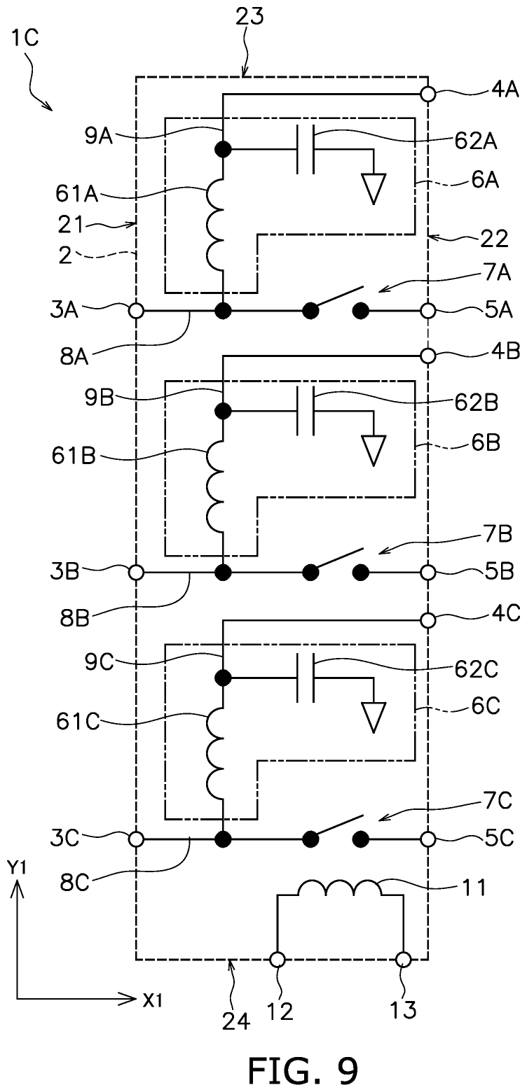

Next, a switching device 1C according to a third embodiment of the claimed invention will be described. FIG. 9 is a diagram showing a configuration of the switching device 1C according to the third embodiment. As shown in FIG. 9, the switching device 1C includes a third DUT terminal 3C, a third DC terminal 4C, a third RF terminal 5C, a third low-pass filter 6C, and a third switching section 7C in addition to the configuration of the switching device 1B according to the second embodiment.

The first to third DUT terminals 3A to 3C, the first to third DC terminals 4A to 4C, the first to third RF terminals 5A to 5C, the first to third low-pass filters 6A to 6C, the first to third switching sections 7A to 7C, the drive section 11, and the first and second drive terminals 12 and 13 are arranged on the base 2. The switching device 1C is modularized by arranging the first to third DUT terminals 3A to 3C, the first to third DC terminals 4A to 4C, the first to third RF terminals 5A to 5C, the first to third low-pass filters 6A to 6C, the first to third switching sections 7A to 7C, the drive section 11, and the first and second drive terminals 12 and 13 on the common base 2.

The configurations of the third DUT terminal 3C, the third DC terminal 4C, and the third RF terminal 5C are the same as those of the first DUT terminal 3A, the first DC terminal 4A, and the first RF terminal 5A, respectively. The third low-pass filter 6C is connected to the third DUT terminal 3C and the third DC terminal 4C. The third low-pass filter 6C includes an inductor 61C and a capacitor 62C. The third low-pass filter 6C has a lower limit of cut frequency set so as to pass the DC signal but cut the RF signal. Other configurations of the third low-pass filter 6C are the same as those of the first low-pass filter 6A.

The third switching section 7C is connected to the third DUT terminal 3C and the third RF terminal 5C. The third switching section 7C is switchable between an on state and an off state. The third switching section 7C electrically connects the third DUT terminal 3C and the third RF terminal 5C in the on state. The third switching section 7C electrically disconnects the third DUT terminal 3C and the third RF terminal 5C in the off state. The drive section 11 switches the first to third switching sections 7A to 7C between the on state and the off state.

In the switching device 1C according to the third embodiment, the first to third switching sections 7A to 7C are set to the on state during the RF test. Thereby, the first DUT terminal 3A and the first RF terminal 5A are electrically connected to each other. The second DUT terminal 3B and the second RF terminal 5B are electrically connected to each other. The third DUT terminal 3C and the third RF terminal 5C are electrically connected to each other. In this state, the RF signal is detected by the ATE through the first DUT terminal 3A and the first RF terminal 5A. The RF signal is detected by the ATE through the second DUT terminal 3B and the second RF terminal 5B. Also, the RF signal is detected by the ATE through the third DUT terminal 3C and the third RF terminal 5C. On the other hand, since the RF signal is cut by the first to third low-pass filters 6A to 6C, the RF signal is prevented from flowing through the first to third DC terminals 4A to 4C.

During the DC test, the first to third switching sections 7A to 7C are set to the off state. Thereby, the first DUT terminal 3A and the first RF terminal 5A are electrically isolated from each other. The second DUT terminal 3B and the second RF terminal 5B are electrically isolated from each other. Also, the third DUT terminal 3C and the third RF terminal 5C are electrically isolated from each other. In this state, the DC signals are prevented from flowing through the first to third RF terminals 5A to 5C. The DC signal is detected by the ATE through the first DUT terminal 3A, the first low-pass filter 6A, and the first DC terminal 4A. The DC signal is detected by the ATE through the second DUT terminal 3B, the second low-pass filter 6B, and the second DC terminal 4B. Further, the DC signal is detected by the ATE through the third DUT terminal 3C, the third low-pass filter 6C, and the third DC terminal 4C. Therefore, the DC signal is detected by the ATE without passing through the first to third switching sections 7A to 7C. As a result, even if the first to third switching sections 7A to 7C are worn out, it is still possible to measure the DC signals stably and accurately.

The first to third DUT terminals 3A to 3C, the first to third DC terminals 4A to 4C, the first to third RF terminals 5A to 5C, and the first and second drive terminals 12 and 13 are arranged on the side edges of the base 2. Specifically, the first to third DUT terminals 3A to 3C are arranged along the first side edge 21. The first to third RF terminals 5A to 5C are arranged along the second side edge 22.

The first DUT terminal 3A and the first RF terminal 5A are arranged side by side in the first direction X1. The first DUT terminal 3A and the first RF terminal 5A are arranged facing each other in the first direction X1. The second DUT terminal 3B and the second RF terminal 5B are arranged side by side in the first direction X1. The second DUT terminal 3B and the second RF terminal 5B are arranged to face each other in the first direction X1. The third DUT terminal 3C and the third RF terminal 5C are arranged side by side in the first direction X1. The third DUT terminal 3C and the third RF terminal 5C are arranged facing each other in the first direction X1.

The base 2 further includes a third RF line 8C and a third DC line 9C in addition to the configuration of the base 2 of the second embodiment. The third RF line 8C extends from the third DUT terminal 3C to the third RF terminal 5C. The third RF line 8C extends linearly in the first direction X1. The third RF line 8C is arranged parallel to the first RF line 8A and the second RF line 8B. The third switching section 7C is connected to the third RF line 8C.

The third DC line 9C extends from the third DUT terminal 3C to the third DC terminal 4C. The third low-pass filter 6C is connected to the third DC line 9C. The first to third DC terminals 4A to 4C are arranged on the second side edge 22. The first and second drive terminals 12 and 13 are arranged on the fourth side edge 24.

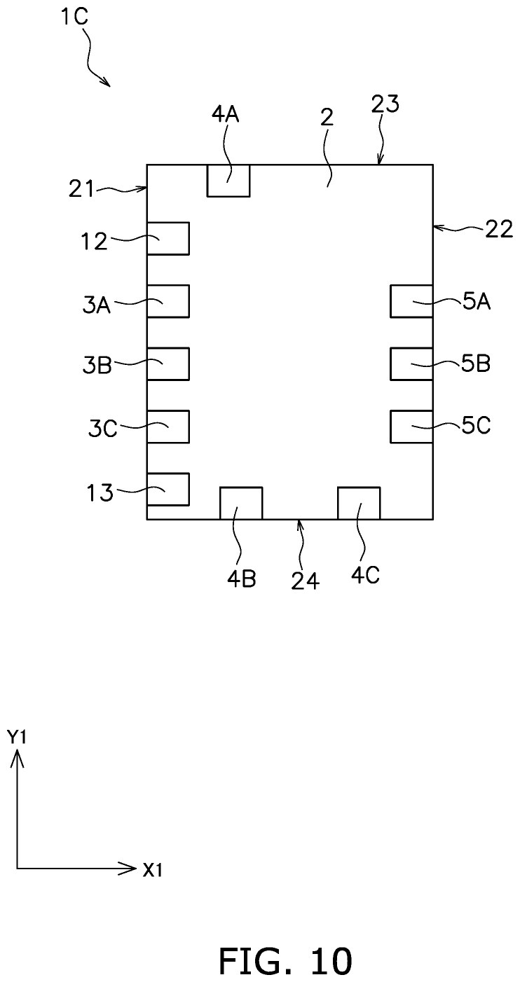

The arrangement of each terminal and each line is not limited to the above and may be changed. For example, FIG. 10 is a diagram showing an arrangement of the terminals according to a modification of the third embodiment of the claimed invention. As shown in FIG. 10, in the modification of the third embodiment, the first to third DUT terminals 3A to 3C are arranged along the first side edge 21. The first to third RF terminals 5A to 5C are arranged along the second side edge 22. The first DUT terminal 3A and the first RF terminal 5A are arranged side by side in the first direction X1. The second DUT terminal 3B and the second RF terminal 5B are arranged side by side in the first direction X1. The third DUT terminal 3C and the third RF terminal 5C are arranged side by side in the first direction X1.

The first drive terminal 12 is arranged on one side of the first to third DUT terminals 3A to 3C on the first side edge 21. The second drive terminal 13 is arranged on the other side of the first to third DUT terminals 3A to 3C on the first side edge 21. The first DC terminal 4A is arranged on the third side edge 23. The second DC terminal 4B and the third DC terminal 4C are arranged on the fourth side edge 24. The arrangement of the first drive terminal 12, the second drive terminal 13, and the first to third DC terminals 4A to 4C may be changed.

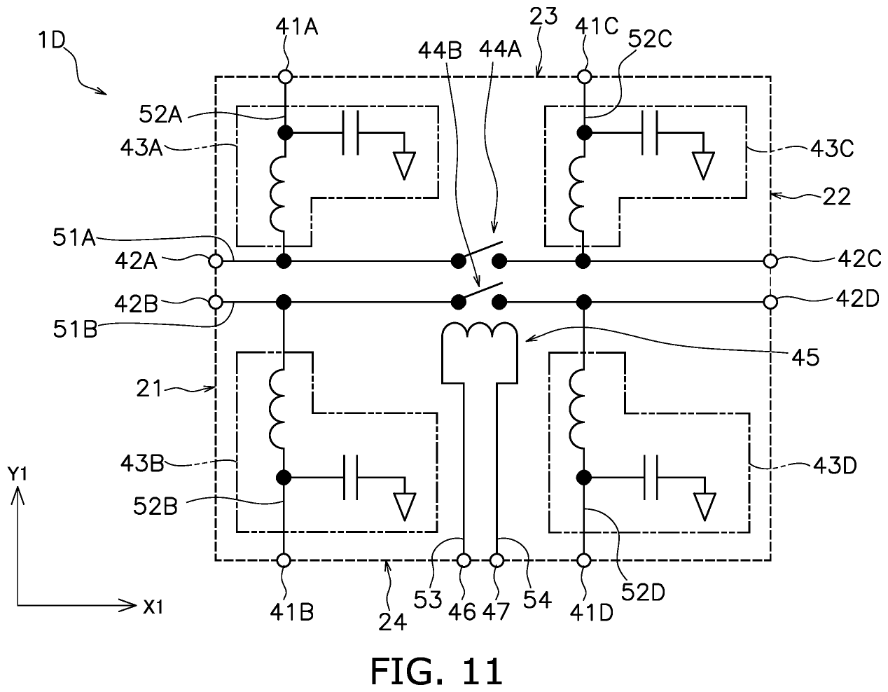

Next, a switching device 1D according to a fourth embodiment of the claimed invention will be described. FIG. 11 is a diagram showing a configuration of the switching device 1D according to the fourth embodiment. The switching device 1D according to the fourth embodiment is a device for switching between the DC test for the device under test and a loopback test for testing the high-frequency characteristics of the device under test. As shown in FIG. 11, the switching device 1D includes first to fourth DC terminals 41A to 41D, first to fourth loopback terminals 42A to 42D, first to fourth low-pass filters 43A to 43D, and first and second switching sections 44A and 44B, a drive section 45, and first and second drive terminals 46 and 47.

The first to fourth DC terminals 41A to 41D, the first to fourth loopback terminals 42A to 42D, the first to fourth low-pass filters 43A to 43D, the first and second switching sections 44A and 44B, the drive section 45, and the first and second drive terminals 46 and 47 are arranged on the base 2. The switching device 1D is modularized by arranging the first to fourth DC terminals 41A to 41D, the first to fourth loopback terminals 42A to 42D, the first to fourth low-pass filters 43A to 43D, the first and second switching sections 44A and 44B, the drive section 45, and the first and second drive terminals 46 and 47 on the common base 2.

The configurations of the first to fourth DC terminals 41A to 41D, the first to fourth loopback terminals 42A to 42D, and the first to fourth low-pass filters 43A to 43D are respectively the same as the first DC terminal 4A, the first RF terminal 5A, and the first low-pass filter 6A of the first embodiment.

The first switching section 44A is connected to the first loopback terminal 42A and the third loopback terminal 42C. The first switching section 44A is switchable between an on state and an off state. The first switching section 44A electrically connects the first loopback terminal 42A and the third loopback terminal 42C in the on state. The first switching section 44A electrically disconnects the first loopback terminal 42A and the third loopback terminal 42C in the off state.

The second switching section 44B is connected to the second loopback terminal 42B and the fourth loopback terminal 42D. The second switching section 44B is switchable between an on state and an off state. The second switching section 44B electrically connects the second loopback terminal 42B and the fourth loopback terminal 42D in the on state. The second switching section 44B electrically disconnects the second loopback terminal 42B and the fourth loopback terminal 42D in the off state.

The drive section 45 switches the first and second switching sections 44A and 44B between the on state and the off state. Other configurations of the first and second switching sections 44A and 44B and the drive section 45 are the same as those of the switching section 7A and the drive section 11 of the first embodiment.

The first to fourth DC terminals 41A to 41D, the first to fourth loopback terminals 42A to 42D, and the first and second drive terminals 46 and 47 are arranged on the side edges of the base 2. Specifically, the first and second loopback terminals 42A and 42B are arranged along the first side edge 21. The third and fourth loopback terminals 42C and 42D are arranged along the second side edge 22. The first and third loopback terminals 42A and 42C are arranged side by side with each other in the first direction X1. The first and third loopback terminals 42A and 42C are arranged facing each other in the first direction X1. The second and fourth loopback terminals 42B and 42D are arranged side by side with each other in the first direction X1. The second and fourth loopback terminals 42B and 42D are arranged facing each other in the first direction X1.

The base 2 includes a first loopback line 51A, a second loopback line 51B, first to fourth DC lines 52A to 52D, a first drive line 53, and a second drive line 54. The configurations of the first to fourth DC lines 52A to 52D and the first and second drive lines 53 and 54 are the same as the first DC line 9A and the first and second drive lines 16 and 17 of the first embodiment.

The first loopback line 51A extends from the first loopback terminal 42A to the third loopback terminal 42C. The first loopback line 51A extends linearly in the first direction X1. The first switching section 44A is connected to the first loopback line 51A. The second loopback line 51B extends from the second loopback terminal 42B to the fourth loopback terminal 42D. The second loopback line 51B extends linearly in the first direction X1. The second loopback line 51B is arranged parallel to the first loopback line 51A. The second switching section 44B is connected to the second loopback line 51B.

The first and third DC terminals 41A and 41C are arranged on the third side edge 23. The second and fourth DC terminals 41B and 41D are arranged on the fourth side edge 24. The first and second drive terminals 46 and 47 are arranged on the fourth side edge 24. It should be noted that the arrangement of each terminal and each line is not limited to the above arrangement, and may be changed.

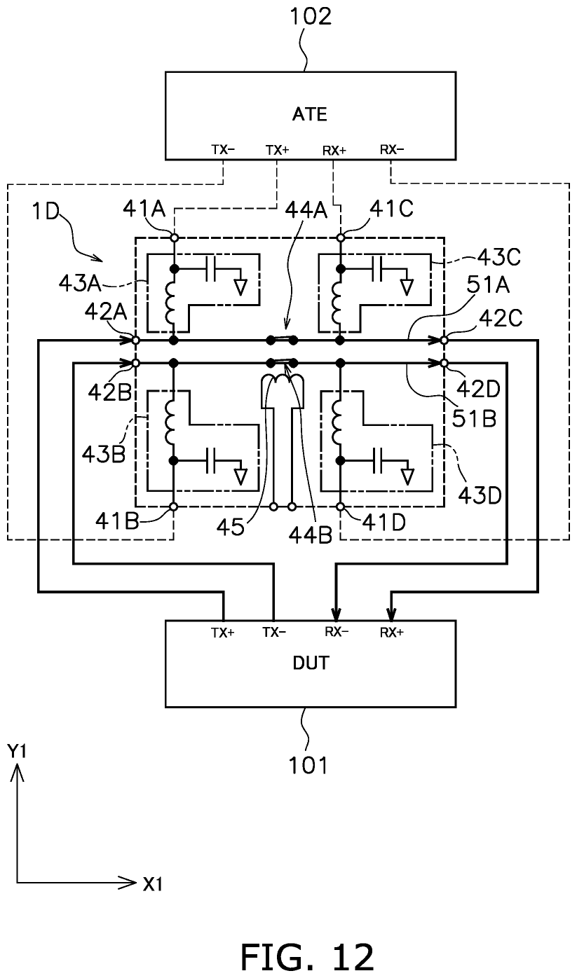

FIG. 12 is a diagram showing the switching device 1D and the signal flow during the loopback test. In the switching device 1D according to the fourth embodiment, the first to fourth loopback terminals 42A to 42D are connected to the DUT 101 in the same way as the RF terminals of the above-described embodiments. In the switching device 1D according to the fourth embodiment, the first and second switching sections 44A and 44B are set to the on state during the loopback test. Thereby, the first loopback terminal 42A and the third loopback terminal 42C are electrically connected to each other. The second loopback terminal 42B and the fourth loopback terminal 42D are electrically connected to each other. In this state, the RF signal returns from the DUT 101 to the DUT 101 through the first loopback terminal 42A and the third loopback terminal 42C. The RF signal returns to the DUT 101 from the DUT 101 through the second loopback terminal 42B and the fourth loopback terminal 42D. On the other hand, since the RF signal is cut by the first to fourth low-pass filters 43A to 43D, the RF signal is prevented from flowing to the first to fourth DC terminals 41A to 41D.

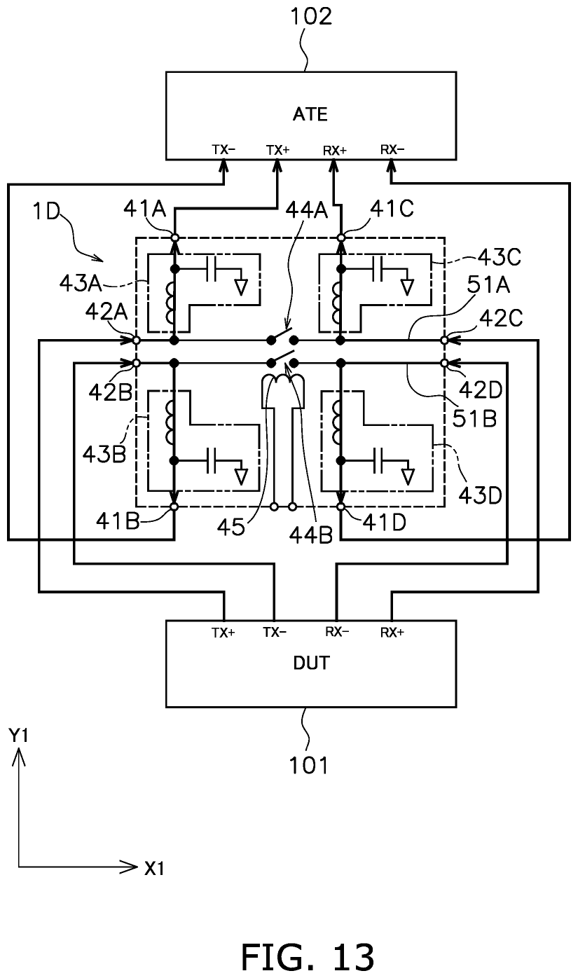

FIG. 13 is a diagram showing the switching device 1D and the signal flow during the DC test. As shown in FIG. 13, during the DC test, the first and second switching sections 44A and 44B are set to the off state. Thereby, the first loopback terminal 42A and the third loopback terminal 42C are electrically isolated from each other. The second loopback terminal 42B and the fourth loopback terminal 42D are electrically isolated from each other. In this state, the DC signal is prevented from flowing between the first loopback terminal 42A and the third loopback terminal 42C. Further, the DC signal is prevented from flowing between the second loopback terminal 42B and the fourth loopback terminal 42D. The DC signal is detected by the ATE 102 from the DUT 101 through the first loopback terminal 42A, the first low-pass filter 43A, and the first DC terminal 41A. Similarly, the DC signal is detected by the ATE 102 through the second to fourth loopback terminals 42B to 42D, the second to fourth low-pass filters 43B to 43D, and the second to fourth DC terminals 41B to 41D. Therefore, the DC signal is detected by the ATE 102 without passing through the first and second switching sections 44A and 44B. Thereby, even if the first and second switching sections 44A and 44B are worn out, stable and highly accurate measurement of the DC signal is still possible.

Although one embodiment of the claimed invention has been described above, the claimed invention is not limited to the above embodiment, and various changes can be made without departing from the scope of the invention.

The switching device may be connected to other test equipments not limited to the ATE. The configuration of the switching device is not limited to that of the above embodiments and may be modified. For example, the configuration of the low-pass filter may be changed. The low-pass filter may be composed of only an inductor. The low-pass filter may include a plurality of inductors. A resistor may be provided instead of the inductor. The low-pass filter may include a plurality of capacitors. The low-pass filter may include a plurality of resistors. The low-pass filter may be a lumped constant circuit or a distributed constant circuit using a wiring pattern on a substrate.

The switching section is not limited to a mechanical relay including contacts. The switching section may be other types of switches such as a reed relay, a mechanical switch, a MOSFET relay, a photocoupler, a semiconductor RF switch, or a MEMS switch. The switching section may be manually switched between the on state and the off state. The switching device may have a normally open or normally closed configuration. The switching device may have a structure in which the operating state of the switching section is maintained without the control signal.

The configuration of the drive section is not limited to that of the above embodiment and may be modified. A plurality of drive sections may be provided according to the plurality of switching sections.

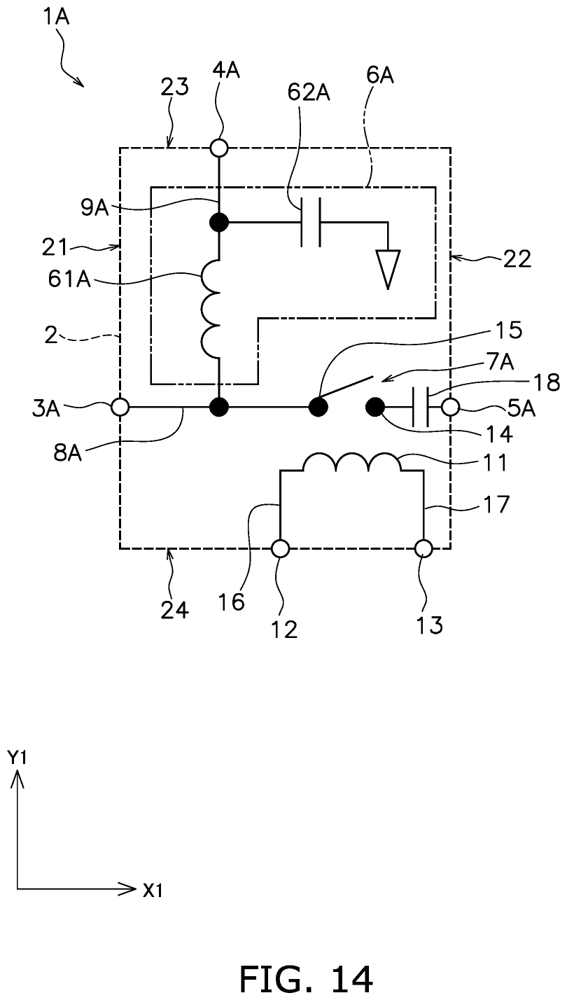

FIG. 14 is a diagram showing a configuration of a switching device 1A according to a modification of the first embodiment of the claimed invention. As shown in FIG. 14, a capacitor 18 may be connected in series with the first switching section 7A. As a result, the superposition of the DC component from the first RF terminal 5A to the ATE 102 is suppressed. A capacitor may be provided in other embodiments as well.

### REFERENCE SIGNS LIST

1A-1B: Switching devices, 2: Base, 3A-3C: First to Third DUT terminals, 4A-4C: First to Third DC terminals, 5A-5C: First to Third RF terminals, 6A-6C: First to Third low-pass filters, 7A-7C: First to Third switching sections, 11: Drive section, 12: First drive terminal, 13: Second drive terminal, 21: First side edge, 22: Second side edge, 23: Third side edge, 24: Fourth side edge, 31-34: First to Fourth ground terminals, 41A-41D: First to Fourth DC terminals, 42A-42D: First to Fourth loopback terminals, 43A-43D: First to Fourth low-pass filters, 44A: First switching section, 44B: Second switching section

1. A switching device for switching between an RF test that tests high-frequency characteristics of a device under test and a DC test that tests DC characteristics of the device under test, the switching device comprising:
a base;
a first DUT terminal for the device under test, the first DUT terminal being arranged on the base;
a first DC terminal for the DC test, the first DC terminal being arranged on the base;
a first RF terminal for the RF test, the first RF terminal being arranged on the base;
a first low-pass filter connected to the first DUT terminal and the first DC terminal; and
a first switching section connected to the first DUT terminal and the first RF terminal, the first switching section being switchable between an on state and an off state, the first switching section being configured to electrically connect the first DUT terminal and the first RF terminal in the on state and electrically disconnect the first DUT terminal and the first RF terminal in the off state.

2. The switching device according to claim 1, further comprising:
a second DUT terminal for the device under test, the second DUT terminal being arranged on the base;
a second DC terminal for the DC test, the second DC terminal being arranged on the base;
a second RF terminal for the RF test, the second RF terminal being arranged on the base;
a second low-pass filter connected to the second DUT terminal and the second DC terminal; and
a second switching section connected to the second DUT terminal and the second RF terminal, the second switching section being switchable between an on state and an off state, the second switching section being configured to electrically connect the second DUT terminal and the second RF terminal in the on state and electrically disconnect the second DUT terminal and the second RF terminal in the off state.

3. The switching device according to claim 2, wherein
the base includes
a first side edge, and
a second side edge opposite the first side edge,
the first DUT terminal and the second DUT terminal are arranged along the first side edge, and
the first RF terminal and the second RF terminal are arranged along the second side edge.

4. The switching device according to claim 3, wherein
the first DUT terminal and the first RF terminal are arranged side by side with each other in a first direction from the first side edge to the second side edge, and
the second DUT terminal and the second RF terminal are arranged side by side in the first direction.

5. The switching device according to claim 3, further comprising:
a first ground terminal arranged on one side of the first DUT terminal and the second DUT terminal on the first side edge, and
a second ground terminal arranged on the other side of the first DUT terminal and the second DUT terminal on the first side edge.

6. The switching device according to claim 3, further comprising:
a third ground terminal arranged on one side of the first RF terminal and the second RF terminal on the second side edge, and
a fourth ground terminal arranged on the other side of the first RF terminal and the second RF terminal on the second side edge.

7. The switching device according to claim 3, wherein
the first DC terminal is arranged between the first DUT terminal and the second DUT terminal on the first side edge.

8. The switching device according to claim 3, wherein
the second DC terminal is arranged between the first RF terminal and the second RF terminal on the second side edge.

9. The switching device according to claim 3, further comprising:
a drive section configured to switch the first switching section and/or the second switching section between the on state and the off state;
a first drive terminal connected to the drive section; and
a second drive terminal connected to the drive section, wherein
the first drive terminal is arranged between the first DUT terminal and the second DUT terminal on the first side edge.

10. The switching device according to claim 3, further comprising:
a drive section configured to switch the first switching section and/or the second switching section between the on state and the off state;
a first drive terminal connected to the drive section; and
a second drive terminal connected to the drive section, wherein
the second drive terminal is arranged between the first RF terminal and the second RF terminal on the second side edge.

11. The switching device according to claim 3, further comprising:
a drive section configured to switch the first switching section and/or the second switching section between the on state and the off state;
a first drive terminal connected to the drive section; and
a second drive terminal connected to the drive section, wherein
the first DUT terminal, the second DUT terminal, the first drive terminal, and the second drive terminal are arranged along the first side edge, and
the first RF terminal, the second RF terminal, the first DC terminal, and the second DC terminal are arranged along the second side edge.

12. The switching device according to claim 3, further comprising:
a drive section configured to switch the first switching section and/or the second switching section between the on state and the off state;
a first drive terminal connected to the drive section; and
a second drive terminal connected to the drive section, wherein
the base includes
a third side edge connected to the first side edge and the second side edge, and
a fourth side edge connected to the first side edge and the second side edge and arranged opposite to the third side edge,
the first DUT terminal and the second DUT terminal are arranged along the first side edge,
the first RF terminal and the second RF terminal are arranged along the second side edge,
the first drive terminal and the second drive terminal are arranged along the third side edge, and
the first DC terminal and the second DC terminal are arranged along the fourth side edge.

13. The switching device according to claim 2, further comprising:
a third DUT terminal for the device under test, the third DUT terminal being arranged on the base;
a third DC terminal for the DC test, the third DC terminal being arranged on the base;
a third RF terminal for the RF test, the third RF terminal being arranged on the base;
a third low-pass filter connected to the third DUT terminal and the third DC terminal; and
a third switching section connected to the third DUT terminal and the third RF terminal, the third switching section being switchable between an on state and an off state, the third switching section being configured to electrically connect the third DUT terminal and the third RF terminal in the on state and electrically disconnect the third DUT terminal and the third RF terminal in the off state.

14. The switching device according to claim 13, wherein
the base includes
a first side edge, and
a second side edge opposite the first side edge,
the first DUT terminal, the second DUT terminal, and the third DUT terminal are arranged along the first side edge,
the first RF terminal, the second RF terminal, and the third RF terminal are arranged along the second side edge,
the first DUT terminal and the first RF terminal are arranged side by side with each other in a first direction from the first side edge to the second side edge,
the second DUT terminal and the second RF terminal are arranged side by side in the first direction, and
the third DUT terminal and the third RF terminal are arranged side by side in the first direction.

15. A switching device for switching between a DC test that tests DC characteristics of a device under test and a loopback test that tests high frequency characteristics of the device under test, the switching device comprising:
a base;
a first DC terminal for the DC test, the first DC terminal being arranged on the base;
a first loopback terminal for the loopback test, the first loopback terminal being arranged on the base;
a second DC terminal for the DC test, the second DC terminal being arranged on the base;
a second loopback terminal for the loopback test, the second loopback terminal being arranged on the base;
a third DC terminal for DC test, the third DC terminal being arranged on the base;
a third loopback terminal for the loopback test, the third loopback terminal being arranged on the base;
a fourth DC terminal for the DC test, the fourth DC terminal being arranged on the base;
a fourth loopback terminal for the loopback test, the fourth loopback terminal being arranged on the base;
a first low-pass filter connected to the first loopback terminal and the first DC terminal;
a second low-pass filter connected to the second loopback terminal and the second DC terminal;
a third low-pass filter connected to the third loopback terminal and the third DC terminal;
a fourth low-pass filter connected to the fourth loopback terminal and the fourth DC terminal;
a first switching section connected to the first loopback terminal and the third loopback terminal, the first switching section being switchable between an on state and an off state, the first switching section being configured to electrically connect the first loopback terminal and the third loopback terminal in the on state and electrically disconnects the first loopback terminal and the third loopback terminal in the off state; and
a second switching section connected to the second loopback terminal and the fourth loopback terminal, the second switching section being switchable between an on state and an off state, the second switching section being configured to electrically connect the second loopback terminal and the fourth loopback terminal in the on state and electrically disconnect the second loopback terminal and the fourth loopback terminal in the off state.

16. The switching device according to claim 15, wherein
the base includes
a first side edge, and
a second side edge arranged opposite to the first side edge,
the first loopback terminal and the second loopback terminal are arranged along the first side edge, and
the third loopback terminal and the fourth loopback terminal are arranged along the second side edge.

17. The switching device according to claim 16, wherein
the first loopback terminal and the third loopback terminal are arranged side by side with each other in a first direction from the first side edge to the second side edge, and
the second loopback terminal and the fourth loopback terminal are arranged side by side in the first direction.
